(19) United States
(12) Patent Application Publication
(10) Pub. No.: US 2016/0029507 A1
(43) Pub. Date: Jan. 28, 2016

(54) ELECTRONIC APPARATUS

(71) Applicant: Kabushiki Kaisha Toshiba, Tokyo (JP)

(72) Inventors: Ippei Kashiwagi, Ome Tokyo (JP); Shuichi Sekine, Hachioji Tokyo (JP)

(21) Appl. No.: 14/660,680

(22) Filed: Mar. 17, 2015

Related U.S. Application Data
(60) Provisional application No. 62/029,846, filed on Jul. 28, 2014.

(51) Int. Cl. H05K 7/14; H05K 1/18; H05K 5/00

(52) U.S. Cl. CPC H05K 7/1427; H05K 5/0017; H05K 5/0086; H05K 1/181; H05K 2201/10098

(57) ABSTRACT

According to one embodiment, an electronic apparatus includes a housing, a circuit board in the housing, and an antenna. The housing includes a wearable surface to contact with a body part of a person. The antenna includes a feed portion and an element portion, the element portion having a shape of a plate raised with respect to the wearable surface, and extending from a distal end of the feeding portion along an end portion of the circuit board.

### CROSS-REFERENCE TO RELATED APPLICATIONS

This application claims the benefit of U.S. Provisional Application No. 62/029,846, filed Jul. 28, 2014, the entire contents of which are incorporated herein by reference.

### FIELD

Embodiments described herein relate generally to an electronic apparatus.

### BACKGROUND

Electronic apparatuses provided with antennas have been provided. In such an electronic apparatus, it is expected that the performance of the antenna will be improved.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view illustrating an electronic apparatus according to the first embodiment;

FIG. 2 is an exemplary perspective view illustrating the inside of a main body as shown in FIG. 1;

FIG. 3 is an exemplary side view illustrating the inside of the main body as shown in FIG. 1;

FIG. 4 is an exemplary view schematically illustrating the structure of an antenna as shown in FIG. 2;

FIG. 5 is an exemplary top view schematically illustrating a mounting position of the antenna as shown in FIG. 2;

FIG. 6 is an exemplary perspective view illustrating the structure of the antenna as shown in FIG. 2;

FIG. 7 is an exemplary side view illustrating the structure of the antenna as shown in FIG. 2;

FIG. 8 is an exemplary top view illustrating the structure of the antenna as shown in FIG. 2;

FIG. 9 is an exemplary view illustrating a simulation result of a radiation characteristic of the antenna as shown in FIG. 2;

FIG. 10 is an exemplary top view schematically illustrating an electronic apparatus according to the second embodiment;

FIG. 11 is an exemplary top view schematically illustrating an electronic apparatus according to the third embodiment;

FIG. 12 is an exemplary view schematically illustrating the structure of an antenna as shown in FIG. 11;

FIG. 13 is an exemplary perspective view illustrating the structure of an antenna according to the fourth embodiment; and

FIG. 14 is an exemplary top view schematically illustrating an electronic apparatus according to the fifth embodiment.

### DETAILED DESCRIPTION

Various embodiments will be described hereinafter with reference to the accompanying drawings.

In general, according to one embodiment, an electronic apparatus comprises a housing, a circuit board in the housing, and an antenna. The housing comprises a wearable surface to contact with a body part of a person. The antenna comprises a feed portion and an element portion, the element portion having a shape of a plate raised with respect to the wearable surface, and extending from a distal end of the feeding portion along an end portion of the circuit board.

The embodiments will be explained with reference to the accompanying drawings.

Some elements are expressed by two or more terms. These terms are merely examples and these elements may be expressed by another or other terms. The other elements, which are not expressed by two or more terms, may be expressed by another or other terms.

The drawings are merely examples, and may differ from when the embodiments are actually realized in terms of, for example, the relationship between thickness and planar dimension and the ratio of thickness of layers. In the drawings, the relationship or ratio of dimensions may be different from figure to figure.

### First Embodiment

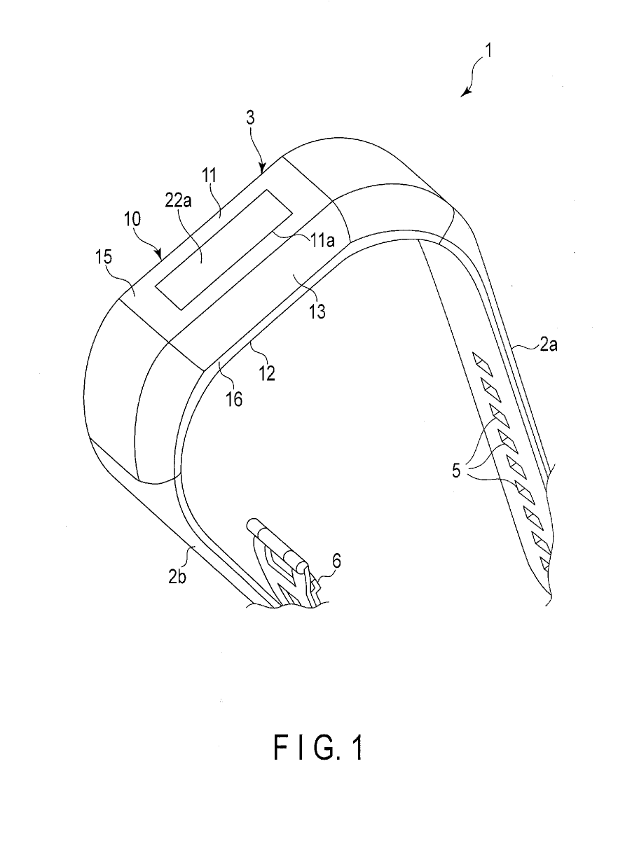

FIGS. 1 to 9 show an electronic apparatus 1 according to a first embodiment. The electronic apparatus 1 is, e.g., a wristband type of wearable terminal (mobile device), and can be used in a state where the electronic apparatus 1 is worn on a user's arm or the like.

FIG. 1 shows an appearance of the electronic apparatus 1. The electronic apparatus 1 comprises, for example, a pair of band portions 2a and 2b and a main body 3. The band portions 2a and 2b are provided on both sides of the main body 3, respectively, and substantially linearly extend from the main body 3. The band portions 2a and 2b are flexible, and can be bent with respect to the main body 3. Also, the band portions 2a and 2b can be wound around the outer periphery of the user's arm.

The pair of band portions 2a and 2b include a first band portion 2a and a second band portion 2b. The first band portion 2a includes a first engagement portion 5. An example of the first engagement portion 5 is each of a plurality of holes arranged in an extending direction of the first band portion 2a. The second band portion 2b includes a second engagement portion 6. An example of the second engagement portion 6 is a projection 6 which can be engaged with any of holes 5 of the first band portion 2a.

In the first embodiment, the first band portion 2a and the second band portion 2b are connected to each other by engaging the second engagement portion 6 with the first engagement portion 5. It should be noted that the first band portion 2a and the second band portion 2b may be formed in advance to have an appropriate elasticity and a shape along the outer periphery of the user's arm so that they can be used without being connected to each other.

As shown in FIG. 1, the main body 3 includes a housing 10. The housing 10 is formed integral with, e.g., the band portions 2a and 2b. Also, the housing 10 includes a display surface 11, a wearable surface 12 and a side surface 13. The display surface 11 is an example of an “upper wall”. The display surface 11 includes a display screen 22a (to be described later) of a display device 22, which is exposed to the outside through an opening portion 11a provided in the display surface 11.

The wearable surface 12 is an example of a “lower wall”. The wearable surface 12 is located opposite to the display surface 11, and also is a surface which will be worn on and in contact with, for example, the user's arm. It should be noted that the wearable surface 12 may be formed to be worn on, for example, a user's finger or another part of the body part of the user. The side surface 13 is an example of a “side wall”. The side surface 13 extends in a thickness direction of the electronic apparatus 1, and connects an edge portion of the display surface 11 and an edge portion of the wearable surface 12.

As shown in FIG. 1, the housing 10 includes a first cover 15 (upper cover) and a second cover 16 (lower cover). The first cover 15, for example, includes the display surface 11 and the entire side surface 13 or part of the side surface 13. The second cover 16, for example, includes the wearable surface 12 and the other part of the side surface 13. In the first embodiment, the housing 10 is formed by combining the first cover 15 and the second cover 16.

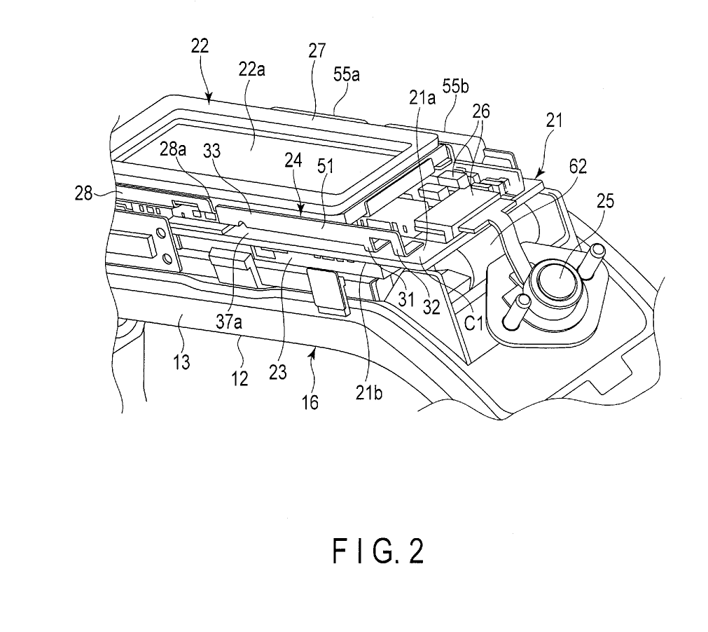

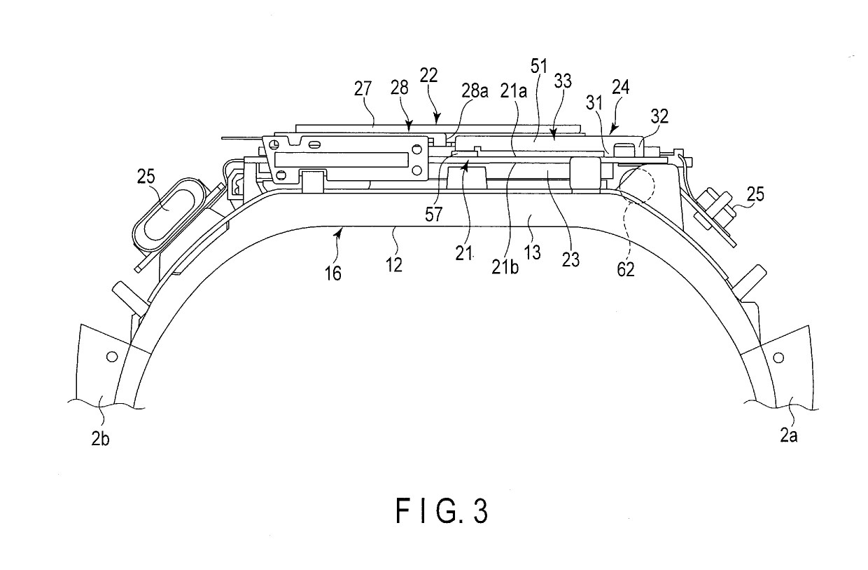

FIGS. 2 and 3 show the inside of the main body 3. In the housing 10, a circuit board 21, the display device 22, a battery 23, an antenna 24 and various kinds of electronic components 25 are accommodated. The circuit board 21 has the shape of, e.g., a substantially rectangular plate. Also, on the circuit board 21, a plurality of electronic components 26 including a CPU are mounted. A longitudinal direction of the circuit board 21 substantially conforms with, e.g., an extending direction of each of the band portions 2a and 2b.

As shown in FIG. 3, the circuit board 21 is provided in substantially parallel with at least part of the wearable surface 12. In the case where the wearable surface 12, for example, is curved, the circuit board 21 is substantially parallel with a center portion of the wearable surface 12. It should be noted that from a different viewpoint, the circuit board 21 is substantially parallel with the display surface of the housing 10 (i.e., it is substantially parallel with the display screen 22a of the display device 22).

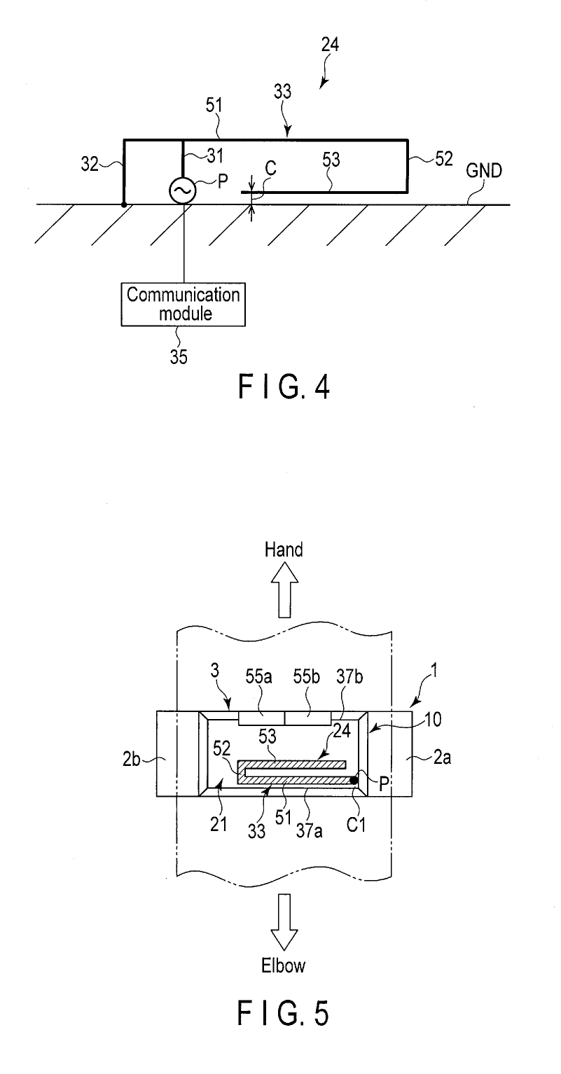

The circuit board 21 includes a first surface 21a and a second surface 21b located opposite to the first surface 21a. Also, the circuit board 21 includes a ground GND (a ground plate, see FIG. 4). The ground GND is provided in an inner layer or the second surface 21b of the circuit board 21.

The display device 22 is provided above the circuit board 21, and faces the first surface 21a of the circuit board 21. The display device 22 is, for example, an organic electroluminescence (organic EL) display. However, it is not limited to the organic EL display, and may be provided as a liquid crystal display or another display. The display device 22 includes a display body 27 and a holder 28 formed of metal. The display body 27 includes the display screen 22a, which can display at least a character or a figure.

The holder 28 is provided along an external form of the display body 27, and covers a peripheral surface and a lower surface of the display body 27. The holder 28 is a fixing member for fixing the display body 27 to the housing 10, for example. However, in place of it, for example, a reinforcing member for reinforcing the display body 27 may be provided.

On the other hand, the battery 23 has a flat and rectangular external form, and is provided under the circuit board 21 to face the second surface 21b of the circuit board 21. That is, the battery 23 is located opposite to the display device 22, with the circuit board 21 interposed between the battery 23 and the display device 22. The battery 23 can be charged by, e.g., an external power supply, and provides necessary power to the electronic apparatus 1.

Next, the antenna 24 will be explained in detail.

The antenna 24 according to the first embodiment is an antenna for a communication system (e.g., Bluetooth, registered trademark) using, e.g., a microwave band, and performs wireless communication using a frequency band of, e.g., 2.4 GHz to 2.5 GHz.

FIG. 4 schematically shows a structure of the antenna 24 according to the first embodiment. The antenna 24 is an inverted F-shaped antenna formed of, e.g., a monopole element, and includes a feeding portion 31, a short-circuit portion 32 and a main body 33. The feeding portion 31 (feeding element) is connected to a feeding point P, and current from the feeding point P flows to the feeding portion 31. To be more specific, the feeding portion 31 is electrically connected to a communication module 35 (wireless module or wireless chip) via the feeding point P. The communication module 35 includes a high-frequency circuit (RF circuit), and performs wireless communication using the antenna 24. The short-circuit portion 32 (short-circuit element) is electrically connected to the ground GND of the circuit board 21. The main body 33 (radiation element) extends from a distal end of the short-circuit portion 32 and a distal end of the feeding portion 31 in substantially parallel with the ground GND.

FIG. 5 schematically shows a mounting position of the antenna 24 according to the first embodiment. It should be noted that the circuit board 21 includes a first end portion 37a and a second end portion 37b. The second end portion 37b is located opposite to the first end portion 37a, and extends in substantially parallel with the first end portion 37a. The first end portion 37a and the second end portion 37b are end portions along an extending direction of the band portions 2a and 2b.

The first end portion 37a is an end portion of the circuit board 21, which is located on a lower side of the circuit board 21 when the pair of band portions 2a and 2b are horizontally held and the display surface 11 is vertically positioned while keeping the character or the figure on the display surface 11 viewed in a regular direction in its initial setting. It should be noted that “regular direction” means a direction in which upper and lower sides of the character or the figure face correctly. The above “keeping . . . in a regular direction in its initial setting” means that the facing direction of an image displayed on the display screen 22a is still not changed (i.e., a default state), for example, in the case where the electronic apparatus 1 includes an acceleration sensor, etc., and the facing direction of the image displayed on the display screen 22a is changed in accordance with the attitude of the electronic apparatus 1. It should be noted that as the character or the figure displayed on the display surface 11, a character or a figure displayed on the display screen 22a may be provided or a character or a figure depicted on a surface of the housing 10 or the like may be provided.

As shown in FIG. 5, the antenna 24 is provided at the first end portion 37a of the circuit board 21. That is, the antenna 24 is provided at an end portion of the circuit board 21, which will be located on an elbow side of the user when the electronic apparatus 1 is worn on the user's arm.

Furthermore, in the first embodiment, the feeding portion 31 (feeding point P) of the antenna 24 is provided at a corner portion C1 of the circuit board 21, which is located on a right lower side of the circuit board 21 when the pair of band portions 2a and 2b are horizontally held and the display surface 11 is vertically positioned while keeping the character or the figure on the display surface 11 viewed in the regular direction in its initial setting. That is, the feeding portion 31 (feeding point P) is provided at the corner portion C1 of the circuit board 21, which will be located at the elbow side and right side (a center side of the body of the user) of the user when the electronic apparatus 1 is worn on the left arm of the user.

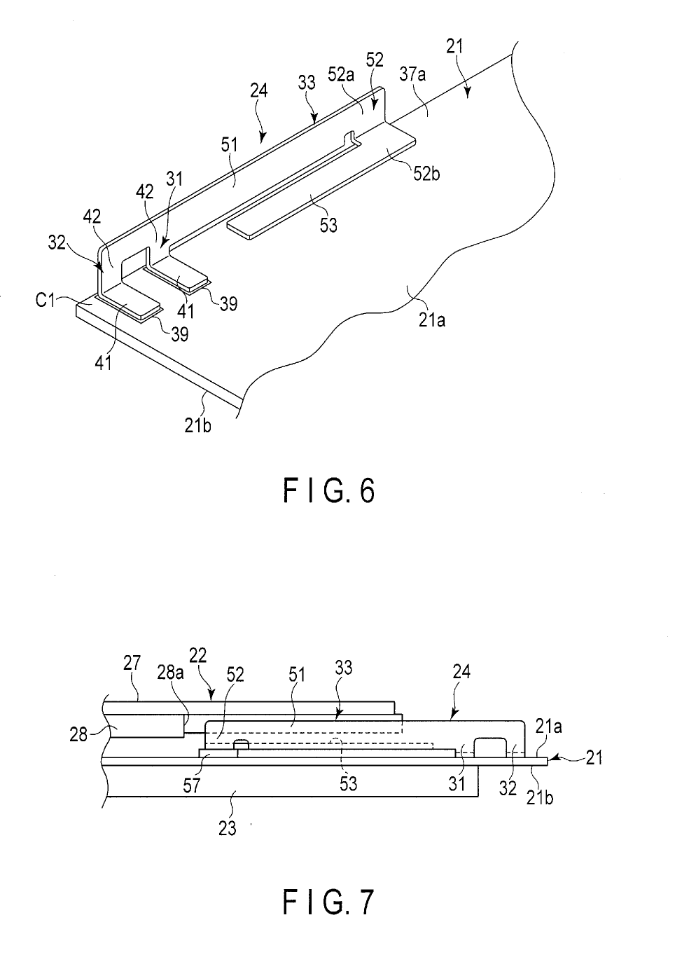

FIG. 6 shows an example of a concrete structure of the antenna 24. The antenna 24 according to the first embodiment is formed of, e.g., metal sheet. That is, the feeding portion 31, the short-circuit portion 32 and the main body 33 each have the shape of a plate. It should be noted that the antenna 24 may be formed on a flexible printed circuit board (FPC) or a printed circuit board (PCB) instead of being formed of metal sheet. It should be noted that the FPC or PCB on which the antenna 24 is provided may be attached to an inner surface of the side surface 13 (side wall) of the housing 10.

As shown in FIG. 6, in the first embodiment, the antenna 24 is fixed to the first surface 21a of the circuit board 21. To be more specific, the first surface 21a of the first end portion 37a of the circuit board 21 includes pads 39 to which the feeding portion 31 and the short-circuit portion 32 are fixed.

The feeding portion 31 and the short-circuit portion 32 include respective fixing portions 41 and respective raised portions 42. The fixing portions 41 are fixed to the pads 39 of the circuit board 21 by, e.g., soldering. The raised portions 42 are bent from the fixing portion 41 and raised from the circuit board 21. In the first embodiment, the raised portions 42 are raised, e.g., in a direction substantially perpendicular to the circuit board 21. By virtue of the above structure, the main body 33 of the antenna 24 is supported by the feeding portion 31 and the short-circuit portion 32, and located apart from the surface of the circuit board 21.

As shown in FIG. 6, the main body 33 of the antenna 24 according to the first embodiment includes a first element portion 51, a folded portion 52 and a second element portion 53. The first element portion 51 substantially extends from the distal end of the short-circuit portion 32 and the distal end of the feeding portion 31 along the first end portion 37a of the circuit board 21. That is, the first element portion 51 extends in the extending direction of the band portions 2a and 2b.

The first element portion 51 has the shape of a plate raised with respect to the wearable surface 12 of the housing 10 (with respect to the first surface 21a of the circuit board 21), and extends along the first end portion 37a of the circuit board 21. In the first embodiment, the first element portion 51 is, for example, substantially perpendicular to the wearable surface 12 of the housing 10. As a result, a plate surface of the first element portion 51 faces an inner surface of the side surface 13 (side wall) of the housing 10.

It should be noted that the above “raised with respect to the wearable surface 12” includes the case where an element is raised at an angle smaller than 90° or an angle greater than 90° with respect to the wearable surface 12 in addition to the case where the element is substantially perpendicular the wearable surface 12. The same is true of the raised portion 31 and the short-circuit portion 32. That is, “raised from the circuit board 21” includes the case where the above element is raised at an angle smaller than 90° or an angle greater than 90° with respect to the circuit board 21, in addition to the case where the element is substantially perpendicular to the circuit board 21.

The folded portion 52 is provided at a distal end portion of the first element portion 51 (i.e., an end portion on an opposite side of the short-circuit portion 32). The second element portion 53 extends from the folded portion 52 in substantially parallel with the first element portion 51. It should be noted that the folded portion 52 is bent at its center portion at, for example, substantially 90°. That is, the folded portion 52 includes a first region 52a connected to the first element portion 51 and substantially parallel with the plate surface of the first element portion 51 and a second region 52b connected to the second element portion 53 and substantially parallel with a plate surface of the second element portion 53. The folded portion 52 is bent such that the angle between the first region 52a and the second region 52b is substantially 90°. Thereby, the plate surface of the second element portion 53 is substantially perpendicular to the plate surface of the first element portion 51.

The second element portion 53 is located inward of the first element portion 51 at the circuit board 21, and overlaps with the circuit board 21 in a thickness direction of the circuit board 21. The second element portion 53 is supported by the folded portion 52, and extends in substantially parallel with the wearable surface 12 (in substantially parallel with the first surface 21a of the circuit board 21) and along the first surface 21a of the circuit board 21. The second element portion 53 overlaps with the ground GND of the circuit board 21 in the thickness direction of the circuit board 21 with a gap between the second element portion 53 and the first surface 21a of the circuit board 21. Thereby, a capacitor C is formed between a distal end portion of the second element portion 53 and the ground GND of the circuit board 21.

As shown in FIG. 5, on the housing 10, at least one button, for example, the button 55a and/or the button 55b is provided. Also, for example, the buttons 55a and 55b are located close to a center portion of the second end portion 37b of the circuit board 21. The second element portion 53 of the antenna 24 extends to the vicinity of the feeding portion 31. Thereby, a distal end (open end) of the second element portion 53 is located closer to the feeding portion 31 than to the buttons 55a and 55b. The distal end of the second element portion 53 is located close to, e.g., the feeding portion 31.

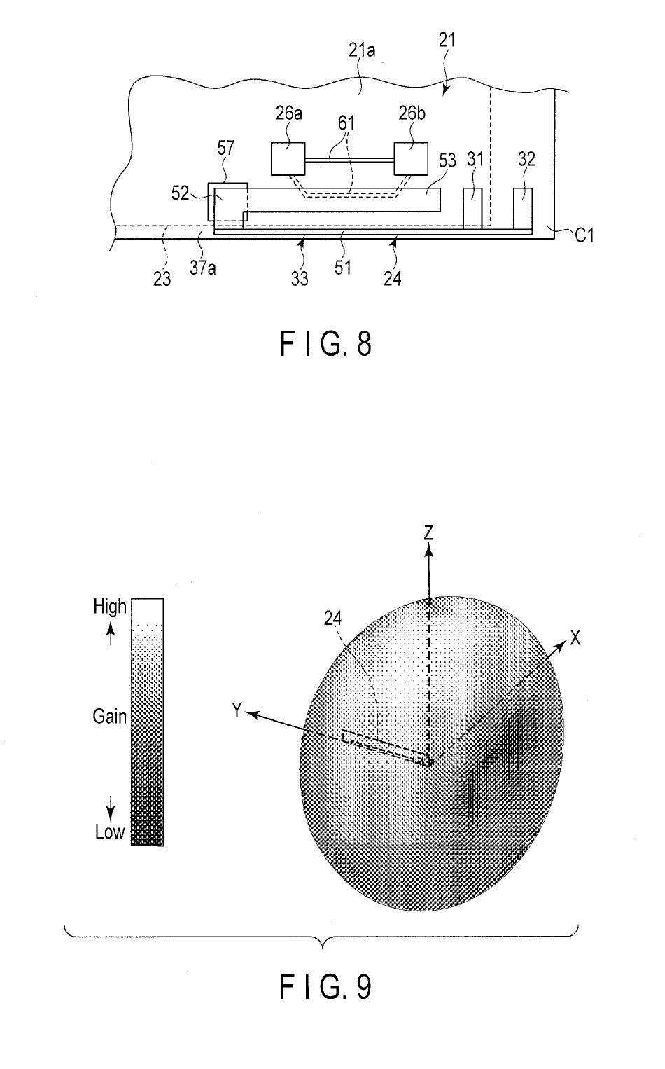

FIGS. 7 and 8 show a relationship in mounting position between the antenna 24 and components located in the vicinity thereof. As shown in FIGS. 7 and 8, a supporter 57 is provided between the first surface 21a of the circuit board 21 and at least one of the folded portion 52 and the second element portion 53 of the antenna 24.

An example of the supporter 57 is an elastic member (e.g., a sponge) having upper and lower surfaces to which double-faced tapes are attached, and is stuck on the antenna 24 and the circuit board 21. Thus, the folded portion 52 and the second element portion 53 of the antenna 24 are supported by the supporter 57. By virtue of this feature, the gap between the second element portion 53 of the antenna 24 and the first surface 21a of the circuit board 21 is maintained, thus suppressing the second element portion 53 from contacting the circuit board 21.

It should be noted that the supporter 57 may be formed by providing a projection at part of the metal sheet forming the antenna 24, and fixing the projection to a pad provided on the circuit board 21, or it may be formed in another manner.

X, Y and Z directions will be defined. The X and Y directions are directions substantially parallel to the first surface 21a of the circuit board 21. The X direction is a direction from the first end portion 37a of the circuit board 21 toward the second end portion 37b. The Y direction is a direction substantially perpendicular to the X direction and along the first end portion 37a. The Z direction is the thickness direction of the circuit board 21.

As shown in FIG. 7, in the first embodiment, as viewed in the X direction (as viewed in a backward direction from the paper surface of FIG. 7), the first element portion 51 of the antenna 24 overlaps with the display device 22. It should be noted that in order to avoid the holder 28 of the display device 22 from overlapping with the first element portion 51 of the antenna 24 as viewed in the X direction, a cut-out portion 28a of the holder 28 is provided to avoid the first element portion 51 of the antenna 24. Thus, even if the antenna 24 is warped toward the display device 22 due to an externally applied impact, the antenna 24 will not come into contact with the holder 28.

As shown in FIG. 8, as viewed in the Z direction (as viewed in a backward direction from the paper surface of FIG. 8), at least part of the antenna (e.g., at least the second element portion 53) overlaps with the battery 23, with the circuit board 21 interposed between the antenna 24 and the battery 23. Furthermore, as viewed in the Z direction, the first element portion 51 of the antenna 24 is displaced from lower region of the display device 22, and the second element portion 53 of the antenna 24 overlaps with the display device 22 (see FIG. 2). The second element portion 53 of the antenna 24 is located between the circuit board 21 and the display device 22.

Furthermore, as shown in FIG. 8, the electronic components 26 mounted on the circuit board 21 include a first electronic component 26a and a second electronic component 26b. The first electronic component 26a and the second electronic component 26b are located in respective areas which do not overlap with the antenna 24, for example, in the thickness direction of the circuit board 21. Between the first electronic component 26a and the second electronic component 26b, a plurality of signal lines 61 (wiring pattern) are provided. In the first embodiment, at least one of the plurality of signal lines 61 may overlap with at least part (e.g., the second element portion 53) of the antenna 24 in the thickness direction of the circuit board 21. However, in this case, the signal lines 61 are not provided on the surface (exposed layer) of the circuit board 21; i.e., they are provided on a layer lower than the exposed layer.

As shown in FIGS. 2 and 3, a vibrator 62 is provided in the housing 10. The vibrator 62 is a rotary vibrator including, e.g., an eccentric portion, and vibrates the housing 10 by rotating the eccentric portion. Upon receipt of a control signal from a CPU, the vibrator 62 vibrates the housing 10 to enable the user to know various states.

According to the first embodiment, the vibrator 62 is located closer to the feeding portion 31 than to the folded portion 52 of the antenna 24. That is, the vibrator 62 is separated from the folded portion 52 and is located close to the feed portion 31 at which the antenna 24 is relatively firmly fixed to the circuit board 21 such that vibration of the vibrator 62 is not easily transmitted to the folded portion 52.

FIG. 9 shows a simulation result of a radiation pattern of the antenna 24. As shown in FIG. 9, in the antenna 24 according to the first embodiment, a region whose gain is high spreads out in a doughnut-shaped radiation pattern whose substantial center is set at the feeding point P and whose center axis is set at a center line extending in the Y direction. That is, a region whose gain is high spreads out also in a direction in which the side surface 13 of the housing 10 faces (i.e., in a direction substantially perpendicular to the wearable surface 12).

In the electronic apparatus 1 having such a structure as described above, a communication performance of the antenna 24 can be improved. For comparison, an electronic apparatus provided with a plate-like antenna element substantially parallel to a circuit board (substantially parallel to a wearable surface) will be considered. When such an electronic apparatus is worn on, e.g., a user's arm, a region whose gain is high spreads out into a region above the user's arm.

On the other hand, as an example of application of a wearable terminal, it can be considered that the wearable terminal wirelessly communicates with another electronic apparatus (e.g., a cell phone or a portable communication terminal) of the user to transmit or receive data or the like. In this case, as is often the case with, the electronic apparatus of the user is inserted in a pocket of the user or it is worn on the upper half of the body part of the user. Thus, in the above electronic apparatus referred to for comparison, it is assumed that there is a case where the position of the region those gain is high does not conform with that of the other electronic apparatus of the user, and the performance of communication between them is not sufficiently ensured.

On the other hand, the electronic apparatus 1 according to the first embodiment comprises the housing 10 including the wearable surface 12 to be worn on a body part of a person, the circuit board 21 provided in the housing 10 and the antenna 24. The antenna 24 includes the feeding portion 31 and the first element portion 51, the feeding portion 31 being raised from the circuit board 21 at the first end portion 37a of the circuit board 21, the first element portion 51 having the shape of a plate and extending from the distal end of the feeding portion 31 along the first end portion 37a of the circuit board 21 such that it is raised with respect to the wearable surface 12. By virtue of such a structure, the region whose gain is high also spreads out in a direction substantially perpendicular to, e.g., the wearable surface 12. That is, in the above structure, the region whose gain is high easily faces the body of the user, and thus its position easily conforms with the position of the other electronic apparatus of the user. Thus, the performance of communication between them can be improved.

Furthermore, in the above structure, the antenna performance can be improved while keeping the size of the antenna 24 relatively small. Thus, in the above structure, the design of the electronic apparatus 1 and the communication performance of the antenna 24 can be improved at the same time.

In the first embodiment, the electronic apparatus 1 further comprises the pair of band portions 2a and 2b provided on the both sides of the housing 10. The first element portion 51 of the antenna 24 extends in the extending direction of the band portions 2a and 2b. In such a structure, the region whose gain is high easily spreads out in an extending direction of the user's arm, and further easily faces the body of the user.

In the first embodiment, the electronic apparatus 1 includes the display surface 11, on which at least a character or a figure is to be displayed. The antenna 24 is provided at an end portion of the circuit board 21, which is located on a lower side of the circuit board 21 when the pair of band portions 2a and 2b are horizontally held and the display surface 21 is vertically positioned while keeping the character or the figure viewed in the regular direction in its initial setting. In such a structure, since the antenna 24 is located at an end portion of the circuit board 21, which will be located close to the elbow of the user, the distance between the antenna 24 and the other electronic apparatus of the user is easily decreased. Thus, the communication performance of the antenna 24 can be further improved. Note that the above-provided explanation is based on the assumption that the display direction of the electronics apparatus 1, in an initial setting, is set as that when the user faces the display surface while the band portions 2a and 2b are open-held horizontally, with the band portion 2b on left and the band portion 2a on right, characters and/or figures can be seen in the regular direction. However, in its initial setting, the display direction of the electronics apparatus 1 may be set as that when the user faces the display surface while the band portions 2a and 2b are open-held vertically, with the band portion 2b up and the band portion 2a down, characters and/or figures (especially, the dial, time information including hour hand and minute hand, etc.) are seen in the regular direction.

In the first embodiment, the feeding portion 31 is provided at a corner portion of the circuit board 21, which is located on a right lower side of the circuit board 21 when the pair of band portions 2a and 2b are horizontally held and the display surface 11 is vertically positioned while keeping the character or the figure viewed in the regular direction in its initial setting. In such a structure, first of all, the short-circuit portion 32 is located at a corner portion of the ground GND. Thus, a current path is not easily divided in the ground GND, and the antenna efficiency can be improved.

Furthermore, in the above structure, when the electronic apparatus 1 is worn on the left hand of the user, the arm of the user is not easily located between the antenna 24 and the body of the user, and the communication of the antenna 24 is not easily influenced by the user's arm. Thereby, the communication performance of the antenna 24 can be further improved.

In the first embodiment, the folded portion 52 is bent such that the second element portion 53 is substantially perpendicular to the first element portion 51. The second element portion 53 has the shape of a plate, and extends along the surface of the circuit board 21 while being located substantially in parallel with the circuit board 21. In such a structure, since the second element portion 53 is substantially parallel to the circuit board 21, for example, the second element portion 53 can be provided between the circuit board 21 and the display device 22, and the size of the electronic apparatus 1 can be made smaller.

In the first embodiment, the second element portion 53 overlaps with the ground GND of the circuit board 21 in the thickness direction of the circuit board 21 with a gap between the second element portion 53 and the circuit board 21. In such a structure, a capacitance C is formed between the distal end of the second element portion 53 and the ground GND. It should be noted that in the case where the plate surface of the second element portion 53 is substantially parallel to the first surface 21a of the circuit board 21, the area of part of the second element portion 53, which faces the circuit board 21, is great, and it is therefore possible to generate a relatively great capacitance C between the distal end of the second element portion 53 and the ground GND. If such a relatively great capacitance C can be generated, the antenna 24 can also be made smaller.

In the first embodiment, there is further provided the supporter 57, which supports the antenna 24, and is located between the circuit board 21 and at least one of the folded portion 52 and the second element portion 53. In such a structure, a free end portion of the antenna 24, which is set in a cantilever state by the feeding portion 31 and the short-circuit portion 32, can be supported by the supporter 57. As a result, the position of the antenna 24 is easily stabilized, and the communication performance of the antenna 24 can thus be improved. It should be noted that in the case where the plate surface of the second element portion 53 is substantially parallel to the first surface 21a of the circuit board 21, the area of part of the folded portion 52 or the second element portion 53, which faces the circuit board 21, is great, and the antenna is further stably supported by the supporter 57.

In the first embodiment, there is further provided the battery 23, which is located opposite to the antenna 24, with the circuit board 21 interposed between the antenna 24 and the battery 23. The second element portion 53 overlaps with the battery 23 in the thickness direction of the circuit board 21. In such a structure, the electronic apparatus 1 can be made further smaller.

In the first embodiment, there are further provided buttons 55a and 55b, which are provided on the housing 10. As a comparative example, it will be considered that the distal end of the second element portion 53 of the antenna 24 is located close to the buttons 55a and 55b. In this case, it is assumed that when the buttons 55a and 55b are operated by the user, a finger of the user influences the antenna 24, thus causing a frequency drift, and as a result worsening the communication performance.

In view of the above, in the first embodiment, the distal end of the second element portion 53 is provided closer to the feeding portion 31 than to the buttons 55a and 55b. In such a structure, since the distal end of the second element portion 53 is separated from the buttons 55a and 55b, the influence of the user's finger, which is exerted at the time of operating the buttons, can be reduced. Thereby, the frequency drift of the antenna 24 can be restricted, and the communication performance can be improved.

In the first embodiment, the electronic apparatus 1 further comprises the vibrator 62 provided in the housing 10. As a comparison example, it will be considered that the vibrator 62 is located close to the folded portion 52. In this case, when the vibrator 62 operates to vibrate the housing 10, there is a possibility that the distance between the circuit board 21 and the folded portion 52 of the antenna 24, which is in the cantilever state, will not be steady due to vibration of the antenna 24 or the circuit board 21.

On the other hand, in the first embodiment, the vibrator 62 is provided closer to the feeding portion 31 than to the folded portion 52 so that it is harder that vibration created by the vibrator 62 is transmitted to the folded portion 52 than to the feeding portion 31. In such a structure, part of the antenna 24 which is close to the vibrator 62 is firmly supported by the feeding portion 31. Thus, even if the vibrator 62 operates, the distance between the antenna 24 and the circuit board 21 is easily steady. This contributes to improvement of the communication performance of the antenna 24.

Electronic apparatuses 1 according to second to fourth embodiments will be explained. It should be noted that with respect to those embodiments, structural elements having the same functions as or similar functions to those in the first embodiment will be denoted by the same reference numerals, and their explanations will be omitted. Also, structures other than a structure made as explained below are the same as those in the first embodiment.

### Second Embodiment

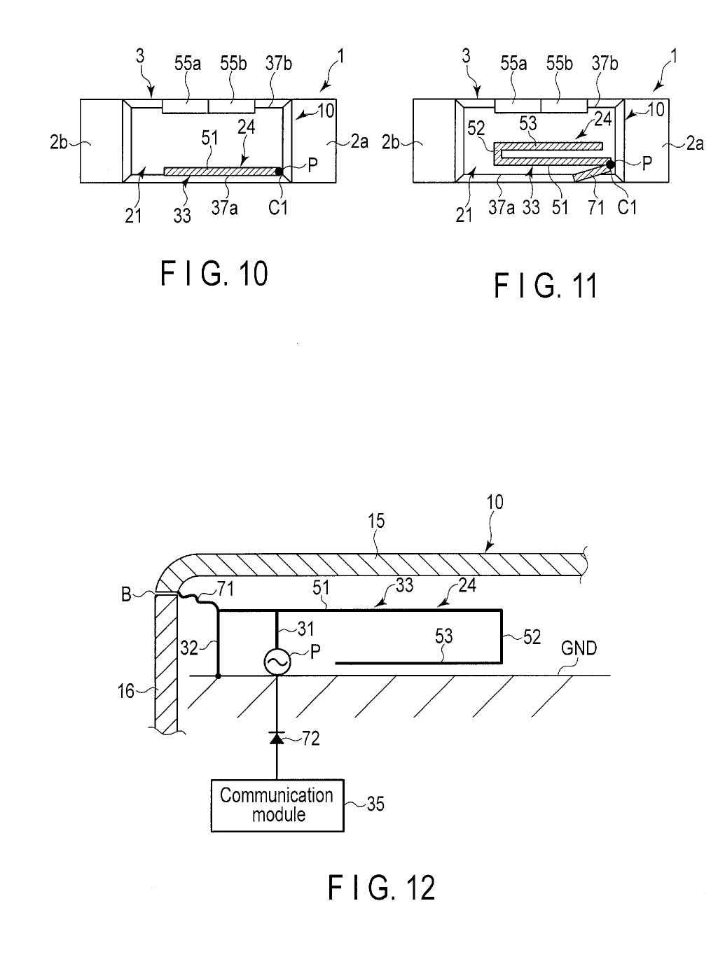

FIG. 10 shows an electronic apparatus 1 according to the third embodiment. In this embodiment, an antenna 24 is substantially linearly shaped. To be more specific, the antenna 24 comprises only the first element portion 51 described in the first embodiment; that is, it does not include the folded portion 52 and the second element portion 53. Also, in such a structure, the communication function of the antenna 24 can be improved as in the first embodiment.

### Third Embodiment

FIGS. 11 and 12 show an electronic apparatus 1 according to the third embodiment. In the third embodiment, an antenna 24 includes a branch element 71. The branch element 71 is an example of a “conductor portion”. For example, the branch element 71 is provided to extend from a short-circuit portion 32 toward an inner surface of a housing 10 and extend in parallel with an outer surface of the housing. The electrical length of the branch element 71 is set to, e.g., 1/12 wavelength or less so as not to influence the characteristics of the antenna 24.

The short-circuit portion 32 is an example of “middle of a part of the antenna, which is connected to the ground”. It should be noted that the branch element 71 is not limited to an element branching from the short-circuit portion 32. For example, it may branch from a part of a main body 33, which is located between the short-circuit portion 32 and a feeding portion 31.

The branch element 71 may be formed of metal sheet as in another portion of the antenna 24, or may be formed of an FPC or a PCB. Also, the branch element 71 is located closer to the inner surface of the housing 10 than the circuit board 21 and the electronic components 25, and thus functions as a lighting rod for static electricity.

As shown in FIG. 12, in the third embodiment, the branch element 71 extends from the short-circuit portion 32 toward a center portion of the side surface 13 of the housing 10. A distal end of the branch element 71 is located closer to the center portion of the side surface 13 of the housing 10 than the feeding portion 31.

As shown in FIG. 12, in the third embodiment, the housing 10 includes a first cover 15 and a second cover 16 which is combined with the first cover 15. Part (e.g., a distal end) of the branch element 71 is located in the vicinity of a boundary B between the first cover 15 and the second cover 16.

Furthermore, as shown in FIG. 12, in the third embodiment, a diode 72 is provided between the feeding point P and a communication module 35. The diode 72 is located in such a way as to pass current flowing from the communication module 35 toward the antenna 24 to, and prevent flowing of current in an opposite direction. By virtue of provision of the diode 72, electricity flowing to the branch element 71 is prevented from flowing toward the communication module 35; that is, backflow is prevented.

By virtue of the above structure, the communication performance of the antenna 24 can be improved as in the first embodiment. Also, in the third embodiment, the antenna 24 includes the branch element 71, which functions as a lighting rod for static electricity. In such a structure, with the antenna 24, which is provided at an end portion 37a of the circuit board 21 and as a result located relatively close to the inner surface of the housing 10, the display device 22, the circuit board 21 and other electronic components 25 and 26 can be protected against static electricity. Thus, the reliability of the electronic apparatus 1 can be improved.

It should be noted that if a member serving to establish a ground is additionally provided in the housing 10 in order to suppress a malfunction due to static electricity, it influences the antenna 24, and may deteriorate the performance of the antenna. Also, if a specific member serving as a countermeasure against static electricity is provided, it may increase the cost of the electronic apparatus 1 and the size of the electronic apparatus 1.

On the other hand, in the third embodiment, a countermeasure against static electricity is taken using the antenna 24. According to such a structure, a member which serves to establish a ground and influences the antenna is not additionally provided, and a specific member serving as a countermeasure against static electricity can be omitted or made smaller. Accordingly, the electronic apparatus 1 can be designed smaller and stronger.

In the third embodiment, the branch element 71 extends from the short-circuit portion 32 toward the center portion of the side surface 13 of the housing 10. In such a structure, it is possible to dissipate static electricity from the side surface 13 of the housing 10, which is relatively frequently contacted by a finger of the user, thus further improving the reliability of the electronic apparatus 1.

As is often the case, static electricity enters the housing 10 from a spatial gap. Therefore, in the third embodiment, a distal end of the branch element 71 is located in the vicinity of the boundary B between the first cover 15 and the second cover 16 of the housing 10. Thereby, even if a gap exits between the first cover 15 and the second cover 16, the components in the housing 10 are easily protected against static electricity.

### Fourth Embodiment

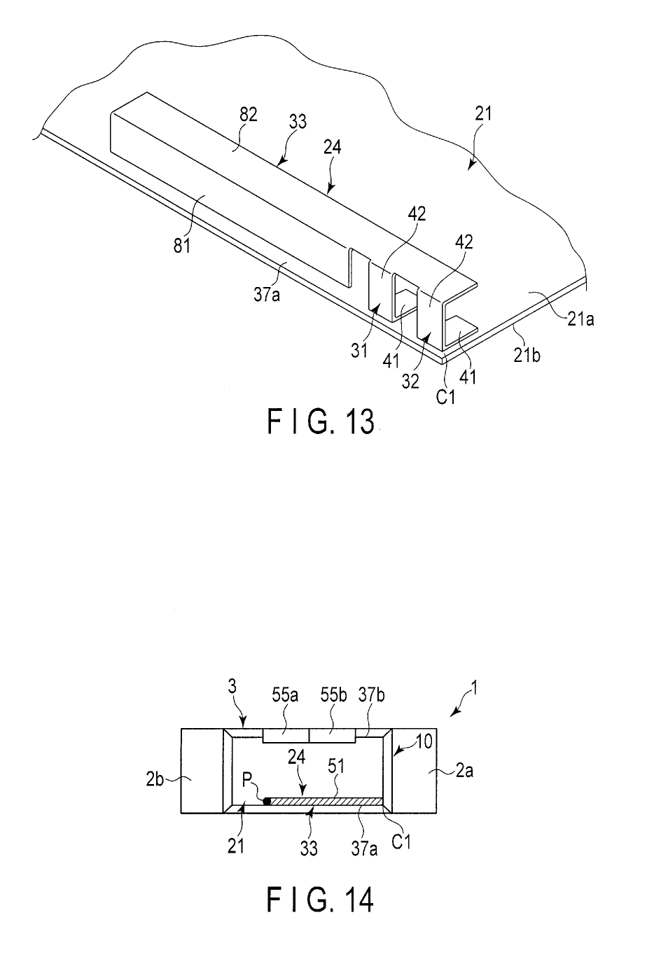

FIG. 13 shows an electronic apparatus 1 according to the fourth embodiment. In the fourth embodiment, the antenna 24 is an antenna (coupler) for near field communication. The antenna 24 transmits and receives data with an electromagnetic coupling (coupling due to electrostatic field [quasi-electrostatic field] or induced electromagnetic field) between the antenna 24 and another antenna (another coupler). The antenna 24 is an antenna for, e.g., TransferJet (registered trademark).

A main body 33 of the antenna 24 includes a first portion 81 substantially perpendicular to a wearable surface 12 and a second portion 82 substantially parallel to the wearable surface 12, and has a substantially L-shaped cross section. By virtue of this feature, the antenna 24 can effect coupling in a first direction where it faces the first portion 81 and in a second direction in which it faces the second portion 82.

Also, in the above structure, the communication function of the antenna 24 can be improved as in the first embodiment. It should be noted that as the antenna 24, for example, an antenna for wireless LAN may be applied.

### Fifth Embodiment

FIG. 14 shows an electronic apparatus 1 according to the fifth embodiment. In the fifth embodiment, a feeding portion 31 (feeding point P) is provided at a midpoint of a first end portion 37a of a circuit board 21, not a corner portion C1 of the circuit board 21. An element portion 51 of the antenna 24 extends from a feeding portion 31 (feeding point P) toward the corner portion C1. Also, in such a structure, for example, even in the case where a communication module 35 (wireless chip) needs to be provided in the vicinity of the center of the circuit board 21, and a wiring pattern is not provided to extend from the communication module 35 to the antenna 24, the communication performance of the antenna 24 can be improved. It should be noted that the structure of the fifth embodiment can also be applied to those of the first, third and fourth embodiments.

In the electronic apparatuses 1 according to the first to fifth embodiments as explained above, the communication performance of the antenna 24 can be improved. It should be noted that the structures of the first to fifth embodiments can be various modified.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a housing comprising a wearable surface to contact with a body part of a person;
a circuit board in the housing; and
an antenna comprising a feeding portion and a first element portion, the feeding portion being raised from the circuit board in an end portion of the circuit board, the first element portion having a shape of a plate raised with respect to the wearable surface, and extending from a distal end of the feeding portion along the end portion of the circuit board.

2. The electronic apparatus of claim 1, wherein the wearable surface is wearable on an arm of a user.

3. The electronic apparatus of claim 2, further comprising a pair of band portions on both sides of the housing,
wherein the first element portion extends in an extending direction of the band portions.

4. The electronic apparatus of claim 3, further comprising a display surface to display at least a character or a figure;
wherein the antenna is provided in an end portion of the circuit board, which is to be located on a lower side of the circuit board when the pair of band portions are held horizontally and the display surface is vertically positioned while keeping the character or the figure viewed in a regular direction as it is in an initial setting.

5. The electronic apparatus of claim 4, wherein the feeding portion is provided in a corner portion of the circuit board, which is to be located on a lower right side of the circuit board when the pair of band portions are held horizontally and the display surface is vertically positioned while keeping the character or the figure viewed in the regular direction as it is in the initial setting.

6. The electronic apparatus of claim 3, wherein the antenna is provided in an end portion of the circuit board, which is to be located on an elbow side of the user when the electronic apparatus is worn on the arm of the user.

7. The electronic apparatus of claim 6, wherein the feeding point is provided in a corner portion of the circuit board, which is to be located on the elbow side of the user and a center side of a body of the user when the electronic apparatus is worn on a left arm of the user.

8. The electronic apparatus of claim 1, wherein the antenna comprises a folded portion at an end portion of the first element portion and a second element portion extending from the folded portion substantially in parallel with the first element portion.

9. The electronic apparatus of claim 8, wherein the folded portion is folded so as to set the second element portion substantially perpendicular to the first element portion, and
the second element portion has a shape of a plate and extends along a surface of the circuit board substantially in parallel with the circuit board.

10. The electronic apparatus of claim 9, wherein
the circuit board comprises a ground, and
the second element portion overlaps with the ground in a thickness direction of the circuit board with a gap between the second element portion and the circuit board.

11. The electronic apparatus of claim 8, further comprising a supporter provided between the circuit board and at least one of the folded portion and the second element portion, and supporting the antenna.

12. The electronic apparatus of claim 8, further comprising a battery located opposite to the antenna, with the circuit board interposed between the battery and the antenna,
wherein the second element portion overlaps with the battery in a thickness direction of the circuit board.

13. The electronic apparatus of claim 8, further comprising a button provided on the housing, and
wherein a distal end of the second element portion is located closer to the feeding portion than to the button.

14. The electronic apparatus of claim 8, further comprising a vibrator in the housing, and
wherein the vibrator is located closer to the feeding portion than to the folded portion to make vibration of the vibrator less transmittable to the folded portion than to the feeding portion.

15. The electronic apparatus of claim 1, wherein the antenna comprises a branch element branching from a middle of a part of the antenna and extending toward an inner surface of the housing, the part of the antenna being connected to a ground.

16. The electronic apparatus of claim 15, wherein the housing comprises a first cover and a second cover combined with the first cover, and a distal end of the branch element is located in a vicinity of a boundary between the first cover and the second cover.

17. An electronic apparatus comprising:
a housing comprising a display surface and a wearable surface located opposite to the display surface;
a circuit board in the housing; and
an antenna comprising a feeding portion and an element portion, the feeding portion being raised from the circuit board in an end portion of the circuit board, the element portion having a shape of a plate raised with respect to the wearable surface, and extending from a distal end of the feeding portion along the end portion of the circuit board.

18. The electronic apparatus of claim 17, further comprising a pair of band portions on both sides of the housing,
wherein the element portion extends in an extending direction of the band portions.

19. The electronic apparatus of claim 18, wherein the antenna is provided in an end portion of the circuit board, which is to be located on a lower side of the circuit board when the pair of band portions are held horizontally and the display surface is vertically positioned while keeping a character or a figure displayed on the display surface viewed in a regular direction as it is in an initial setting.

20. The electronic apparatus comprising:
a housing comprising a wearable surface to contact with a body part of a person;
a circuit board in the housing; and
an antenna comprising a feed portion and an element portion, the element portion having a shape of a plate raised with respect to the wearable surface, and extending from a distal end of the feeding portion along an end portion of the circuit board.
